(19) United States
(12) Patent Application Publication
(10) Pub. No.: US 2026/0052985 A1
(43) Pub. Date: Feb. 19, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Donghun Lee, Suwon-si (KR); Seungduk Baek, Suwon-si (KR)

(21) Appl. No.: 19/293,548

(22) Filed: Aug. 7, 2025

(30) Foreign Application Priority Data
Aug. 19, 2024 (KR) 10-2024-0110189

(51) Int. Cl. H01L 23/373; H01L 23/00; H01L 25/18; H10B 80/00; H10D 80/30

(52) U.S. Cl. CPC H01L 23/3738; H01L 24/08; H01L 24/32; H01L 25/18; H10B 80/00; H10D 80/30; H01L 24/16; H01L 24/73; H01L 2224/08145; H01L 2224/16148; H01L 2224/32145; H01L 2224/32225; H01L 2224/73204; H01L 2225/06524; H01L 2225/06541

(57) ABSTRACT

An example of a semiconductor package includes a buffer die having a first planarize area, a memory die stack structure including middle core dies and a top core die stacked on the buffer die in a vertical direction and having a second planar area smaller than the first planar area, an adhesion layer contacting an upper surface of the memory die stack structure, a dummy die contacting the adhesion layer and having a third planar area greater than the first planar area, and a molding structure under the dummy die and covering sidewalls of the buffer die, the memory die stack structure and the adhesion layer.

### CROSS-REFERENCE TO RELATED APPLICATION

This application claims priority under 35 U.S.C. § 119 to Korean Patent Application No. 10-2024-0110189, filed on Aug. 19, 2024, in the Korean Intellectual Property Office (KIPO), the contents of which are herein incorporated by reference in their entirety.

### BACKGROUND

A multi-chip package may be manufactured by stacking a plurality of chips on a package substrate. If the plurality of chips include different types of chips, coefficient of thermal expansions (CTEs) or warpages of the chips are different from each other, and thus delamination may occur at a boundary of the chips when the multi-chip package is manufactured.

### SUMMARY

Example implementations provide a semiconductor package having enhanced electrical characteristics.

Example implementations provide a method of manufacturing a semiconductor package having enhanced electrical characteristics.

According to example implementations, a semiconductor package is provided. The semiconductor package may include a buffer die having a first planarize area, a memory die stack structure including middle core dies and a top core die stacked on the buffer die in a vertical direction and having a second planar area smaller than the first planar area, an adhesion layer contacting an upper surface of the memory die stack structure, a dummy die contacting the adhesion layer and having a third planar area greater than the first planar area, and a molding member under the dummy die and covering sidewalls of the buffer die, the memory die stack structure and the adhesion layer.

According to example implementations, a semiconductor package is provided. The semiconductor package may include a logic chip having a first planarize area, a memory chip stack structure including first memory chips stacked on the logic chip in a vertical direction and bonded with the logic chip through a first bonding layer structure including a first bonding pad structure, a second memory chip on the memory chip stack structure and bonded with the memory chip stack structure through a second bonding layer structure including a second bonding pad structure, a dummy chip on the second memory chip and bonded with the second memory chip through an adhesion layer and having a second planar area greater than the first planar area, and a molding member under the dummy chip and covering sidewalls of the logic chip, the memory chip stack structure, the second memory chip, the first and second bonding layer structures and the adhesion layer.

According to example implementations, a semiconductor package is provided. The semiconductor package may include a logic chip, a memory chip stack structure, a second memory chip, a dummy chip, a molding member and a conductive bump. The logic chip may have a first planarize area. The memory chip stack structure may include first memory chips stacked on the logic chip in a vertical direction. The first memory chips may be bonded with each other through a first bonding layer structure including a first bonding pad structure. The memory chip stack structure may be bonded with the logic chip through a second bonding layer structure including a second bonding pad structure. The memory chip stack structure may have a second planar area smaller than the first planar area. The second memory chip may be disposed on the memory chip stack structure, and may be bonded with the memory chip stack structure through a third bonding layer structure including a second bonding pad structure. The second memory chip may have the second planar area. The dummy chip may be disposed on the second memory chip, and may be bonded with the second memory chip through an adhesion layer. The dummy chip may have a third planar area greater than the first planar area. The molding member may be disposed under the dummy chip, and may cover sidewalls of the logic chip, the memory chip stack structure, the second memory chip, the first to third bonding layer structures and the adhesion layer. The conductive bump may contact a lower surface of the logic chip.

According to example implementations, a method of manufacturing a semiconductor package is provided. In the method, a first wafer including a die region and a scribe lane region may be provided. A first semiconductor chip may be bonded on an upper surface of the die region of the first wafer using an adhesion layer. The first semiconductor chip may have a first planar area. Second semiconductor chips may be stacked on the first semiconductor chip to form a second semiconductor chip stack structure having a second planar area. A third semiconductor chip may be mounted on the second semiconductor chip stack structure. The third semiconductor chip may have a third planar area greater than the first and second planar areas. A molding member may be formed on the first wafer to cover sidewalls of the adhesion layer, the first semiconductor chip, the second semiconductor chip stack structure and the third semiconductor chip. The first wafer may be sawed along the scribe lane region to form a dummy chip having a fourth planar area greater than the third planar area.

In example embodiments, each of the first and second semiconductor chips may include a memory chip, and the third semiconductor chip includes a logic chip.

In example embodiments, when the second semiconductor chips are stacked on the first semiconductor chip to form the second semiconductor chip stack structure, a first bonding layer including a first bonding pad may be formed on an upper surface of the first semiconductor chip. A respective second bonding layer including a respective second bonding pad may be formed on a first surface of each of the second semiconductor chips. A lowermost second semiconductor chip of the second semiconductor chips may be bonded to the first semiconductor chip by bonding the second bonding layer of the lowermost second semiconductor chip to the first bonding layer of the first semiconductor chip such that the second bonding pad in the second bonding layer of the lowermost second semiconductor chip may contact the first bonding pad in the first bonding layer.

In example embodiments, each of the first and second bonding layers may include silicon carbonitride and/or silicon oxide, and each of the first and second bonding pads may include copper.

In example embodiments, when the second semiconductor chips are stacked on the first semiconductor chip to form the second semiconductor chip stack structure, a respective third bonding layer including a respective third bonding pad may be formed on a second surface of each of the second semiconductor chips. The second bonding layer of another second semiconductor chip of the second semiconductor chips may be bonded to the third bonding layer of the lowermost second semiconductor chip of the second semiconductor chips such that the second bonding pad in the second bonding layer of the another second semiconductor chip may contact the third bonding pad in the third bonding layer of the lowermost second semiconductor chip.

In example embodiments, the third bonding layer may include silicon carbonitride and/or silicon oxide, and the third bonding pad may include copper.

In example embodiments, when the third semiconductor chip is stacked on the second semiconductor chip stack structure, a first bonding layer including a first bonding pad may be formed on an upper surface of an uppermost second semiconductor chip of the second semiconductor chips. A second bonding layer including a second bonding pad may be formed on a surface of the third semiconductor chip. The second bonding layer of the third semiconductor chip may be bonded to the first bonding layer of the uppermost second semiconductor chip of the second semiconductor chips such that the first bonding pad of the first bonding layer may contact the second bonding pad of the second bonding layer.

In example embodiments, each of the first and second bonding layers may include silicon carbonitride and/or silicon oxide, and each of the first and second bonding pads may include copper.

In example embodiments, the first wafer may include a semiconductor material.

In example embodiments, the adhesion layer may include non-conductive film (NCF) and/or die attach film (DAF).

In example embodiments, after sawing the first wafer along the scribe lane region to form the dummy chip, a conductive bump that contacts a surface of the third semiconductor chip may be formed.

In example embodiments, a second wafer including a die region and a scribe lane region may be provided. The second wafer may be sawn along the scribe lane region to form the third semiconductor chip.

According to example implementations, a method of manufacturing a semiconductor package is provided. In the method, a wafer including a die region and a scribe lane region may be provided. A first memory chip may be bonded on an upper surface of the die region of the wafer using an adhesion layer. A plurality of second semiconductor chips may be bonded on an upper surface of the first memory chip using a first bonding layer structure including a first bonding pad structure. A logic chip may be bonded on an upper surface of an uppermost one of the second memory chips using a second bonding layer structure including a second bonding pad structure. A molding member may be formed on the wafer to cover sidewalls of the adhesion layer, the first memory chip, the second memory chips and the logic chip. The wafer may be sawed along the scribe lane region to form a dummy chip.

In example embodiments, the dummy chip may include a semiconductor material.

In example embodiments, each of the first and second bonding layer structures may include silicon carbonitride and/or silicon oxide, and each of the first and second bonding pad structures may include copper.

In example embodiments, the adhesion layer may include non-conductive film (NCF) and/or die attach film (DAF).

In example embodiments, after sawing the wafer along the scribe lane region to form the dummy chip, a conductive bump that contacts a surface of the logic chip may be formed.

According to example implementations, a method of manufacturing a semiconductor package is provided. In the method, a first wafer including a die region and a scribe lane region may be provided. A first memory chip may be bonded on an upper surface of the die region of the first wafer using an adhesion layer. The first memory chip may have a first planar area. A plurality of second memory chips may be bonded on an upper surface of the first memory chip using a first bonding layer structure including a first bonding pad structure to form a second memory chip stack structure having the first planar area. A logic chip may be bonded on an upper surface of the second memory chip stack structure using a second bonding layer structure including a second bonding pad structure. The logic chip may have a second planar area greater than the first planar area. A molding member may be formed on the first wafer to cover sidewalls of the adhesion layer, the first memory chip, the second memory chip stack structure and the logic chip. The first wafer may be sawed along the scribe lane region to form a dummy chip having a third planar area greater than the second planar area.

In example embodiments, each of the first and second bonding layer structures may include silicon carbonitride and/or silicon oxide, and each of the first and second bonding pad structures may include copper.

In example embodiments, a second wafer including a die region and a scribe lane region may be provided. The second wafer may be sawn along the scribe lane region to form the logic chip.

In the semiconductor package in accordance with example implementations, delamination may not occur at a boundary between the buffer die and the core die, and the semiconductor package may have an enhanced heat emission characteristic. Additionally, cost for manufacturing the semiconductor package may be reduced.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure. It is to be understood that the various exemplary implementations shown in the figures are merely illustrative representations and are not necessarily drawn to scale.

FIG. 1 is a cross-sectional view illustrating a semiconductor package in accordance with example implementations.

FIGS. 2 to 11 are cross-sectional views illustrating a method of manufacturing a semiconductor package in accordance with example implementations.

FIGS. 12 and 13 are cross-sectional views illustrating semiconductor packages in accordance with example implementations.

FIG. 14 is a cross-sectional view illustrating a semiconductor package in accordance with example implementations.

FIG. 15 is a cross-sectional view illustrating a semiconductor package in accordance with example implementations.

FIG. 16 is a cross-sectional view illustrating an electronic device in accordance with example implementations.

### DETAILED DESCRIPTION

Hereinafter, example implementations will be explained in detail with reference to the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of present disclosures.

Hereinafter, a direction parallel to an upper surface of a wafer or a substrate may be referred to as a horizontal direction, and a direction perpendicular to the upper surface of the wafer or the substrate may be referred to as a vertical direction.

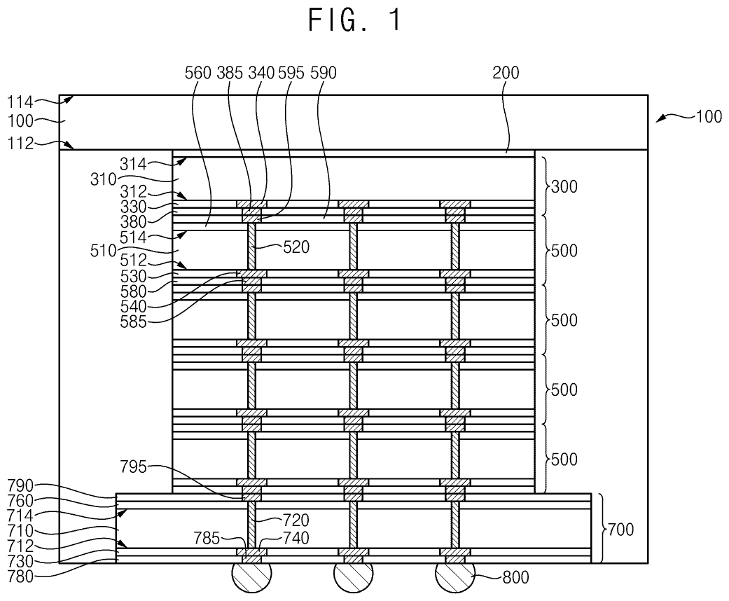

FIG. 1 is a cross-sectional view illustrating a semiconductor package in accordance with example implementations.

Referring to FIG. 1, the semiconductor package may include a second semiconductor chip stack structure, a first semiconductor chip 300, a first adhesion layer 200 and a dummy chip 100 sequentially stacked on a third semiconductor chip 700 in the vertical direction, and a molding member 600 that are disposed under the dummy chip 100 and cover sidewalls of the third semiconductor chip 700, the second semiconductor chip stack structure, the first semiconductor chip 300 and the first adhesion layer 200. The molding member can also be referred to as a molding structure in the present disclosure.

The second semiconductor chip stack structure may include a plurality of second semiconductor chips 500 that are sequentially stacked in the vertical direction and bonded with each other by a hybrid copper bonding (HCB) process. FIG. 1 shows that the second semiconductor chip stack structure includes four second semiconductor chips 500 stacked in the vertical direction, however, the present disclosure is not necessarily limited thereto.

In example implementations, the third semiconductor chip 700 may be a buffer die, and may include a logic device, e.g., a controller. Each of the first and second semiconductor chips 300 and 500 may be a core die, and may include a memory device. Thus, the third semiconductor chip 700 may also be referred to as a logic die or a logic chip, and each of the first and second semiconductor chips 300 and 500 may also be referred to as a memory die or a memory chip.

Each of the second semiconductor chips 500 may be a middle core die, and the first semiconductor chip 300 may be a top core die.

Additionally, the second semiconductor chip stack structure together with the first semiconductor chip 300 may also be referred to as a memory chip stack structure or a memory die stack structure, and the dummy chip 100 may also be referred to as a dummy die 100.

In example implementations, the semiconductor package may be a high bandwidth memory (HBM) package.

The third semiconductor chip 700 may include a fourth substrate 710 having first and second surfaces 712 and 714 opposite to each other in the vertical direction, a first through electrode 720 extending through the fourth substrate 710, a fifth insulating interlayer, a sixth insulating interlayer 730 and a passivation layer 780 sequentially stacked in the vertical direction on the first surface 712 of the fourth substrate 710, a first protective pattern structure 760 on the second surface 714 of the fourth substrate 710, and a fourth bonding layer 790 on the first through electrode 720 and the first protective pattern structure 760.

The fourth substrate 710 may include a semiconductor material, e.g., silicon, germanium, silicon-germanium, or a III-V group compound semiconductor, e.g., GaP, GaAs, GaSb, etc. In example implementations, the fourth substrate 710 may be a silicon-on-insulator (SOI) substrate or a germanium-on-insulator (GOI) substrate.

The fourth substrate 710, that is, the third semiconductor chip 700 may have a first planar area in the horizontal direction.

A circuit device, e.g., a logic device may be disposed on the first surface 712 of the fourth substrate 710, and thus the first surface 712 may be an active surface of the fourth substrate 710. The circuit device may include circuit patterns, which may be covered by the fifth insulating interlayer.

The sixth insulating interlayer 730 may include a third wiring structure 740 therein. The third wiring structure 740 may include, e.g., wirings, vias, contact plugs, etc., and FIG. 1 shows only a single layer for the third wiring structure 740 in order to avoid the complexity of the drawing.

The first through electrode 720 may extend through the fourth substrate 710 in the vertical direction. A portion of the first through electrode 720 may protrude upwardly in the vertical direction, which may be referred to as a protrusion portion. In example implementations, a plurality of first through electrodes 720 may be spaced apart from each other in the horizontal direction. Each of the first through electrodes 720 may have a shape of, e.g., a circle, an ellipse, a polygon, a polygon with rounded corners, etc., in a plan view.

In an example implementation, the first through electrode 720 may extend through the fourth substrate 710, and may contact a portion of the circuit patterns in the fifth insulating interlayer to be electrically connected thereto. Alternatively, the first through electrode 720 may extend through the fourth substrate 710 and the fifth insulating interlayer, and may contact a portion of the third wiring structure 740 in the sixth insulating interlayer 730 to be electrically connected thereto.

The first protective pattern structure 760 may be disposed on the second surface 714 of the fourth substrate 710, and may surround the protrusion portion of the first through electrode 720. In an example implementation, the first protective pattern structure 760 may include first and second protective patterns stacked in the vertical direction. The first protective pattern may include an oxide, e.g., silicon oxide, and the second protective pattern may include an insulating nitride, e.g., silicon nitride.

A fourth bonding pad 795 may be disposed in the fourth bonding layer 790, and may contact an upper surface of the first through electrode 720. A plurality of fourth bonding pads 795 may be spaced apart from each other in the horizontal direction according to a layout of the first through electrodes 720.

A first conductive pad 785 may be disposed in the passivation layer 780, and may contact a portion of the third wiring structure 740 to be electrically connected thereto. A plurality of first conductive pads 785 may be spaced apart from each other in the horizontal direction.

Each of the second semiconductor chips 500 may include a third substrate 510 having first and second surfaces 512 and 514 opposite to each other in the vertical direction, a second through electrode 520 extending through the third substrate 510, a third insulating interlayer, a fourth insulating interlayer 530 and a second bonding layer 580 sequentially stacked in the vertical direction on the first surface 512 of the third substrate 510, a second protective pattern structure 560 on the second surface 514 of the third substrate 510, and a third bonding layer 590 on the second through electrode 520 and the second protective pattern structure 560.

The third substrate 510 may include a semiconductor material, e.g., silicon, germanium, silicon-germanium, or a III-V group compound semiconductor, e.g., GaP, GaAs, GaSb, etc. In example implementations, the third substrate 510 may be a SOI substrate or a GOI substrate.

The third substrate 510, that is, the second semiconductor chip 500 may have a second planar area in the horizontal direction. In example implementations, the second planar area of the third substrate 510 may be smaller than the first planar area of the fourth substrate 710. Thus, an edge portion of the third semiconductor chip 700 may not overlap the second semiconductor chip 500 in the vertical direction. In an example implementation, sidewalls of the second semiconductor chips 500 included in the second semiconductor chip stack structure may be aligned with each other in the vertical direction.

A circuit device, e.g., a volatile memory device such as a DRAM device, an SRAM device, etc., or a non-volatile memory device such as a flash memory device, an EEPROM device, etc., may be disposed on the first surface 512 of the third substrate 510, and thus the first surface 512 facing the third semiconductor chip 700 may be an active surface of the third substrate 510. The circuit device may include circuit patterns, which may be covered by the third insulating interlayer.

The fourth insulating interlayer 530 may include a second wiring structure 540 therein. The second wiring structure 540 may include, e.g., wirings, vias, contact plugs, etc., and FIG. 1 shows only a single layer for the second wiring structure 540 in order to avoid the complexity of the drawing.

The second through electrode 520 may extend through the third substrate 510 in the vertical direction. A portion of the second through electrode 520 may protrude upwardly in the vertical direction, which may be referred to as a protrusion portion. In example implementations, a plurality of second through electrodes 520 may be spaced apart from each other in the horizontal direction, and each of the second through electrodes 520 may have a shape of, e.g., a circle, an ellipse, a polygon and a polygon with rounded corners in a plan view.

In an example implementation, the second through electrode 520 may extend through the third substrate 510, and may contact a portion of the circuit patterns in the third insulating interlayer to be electrically connected thereto. Alternatively, the second through electrode 520 may extend through the third substrate 510 and the third insulating interlayer, and may contact a portion of the second wiring structure 540 in the fourth insulating interlayer 530 to be electrically connected thereto.

The second protective pattern structure 560 may be disposed on the second surface 514 of the third substrate 510, and may surround the protrusion portion of the second through electrode 520. In an example implementation, the second protective pattern structure 560 may include third and fourth protective patterns stacked in the vertical direction. The third protective pattern may include an oxide, e.g., silicon oxide, and the fourth protective pattern may include an insulating nitride, e.g., silicon nitride.

A third bonding pad 595 may be disposed in the third bonding layer 590, and may contact an upper surface of the second through electrode 520. A plurality of third bonding pads 595 may be spaced apart from each other in the horizontal direction according to a layout of the second through electrodes 520.

A second conductive pad 585 may be disposed in the second bonding layer 580, and may contact a portion of the second wiring structure 540 to be electrically connected thereto. A plurality of second conductive pads 585 may be spaced apart from each other in the horizontal direction.

In example implementations, the second bonding layer 580 of a lowermost one of the second semiconductor chips 500 included in the second semiconductor chip stack structure may be bonded to the fourth bonding layer 790 of the first semiconductor chip 700 to form a first bonding layer structure, and the second bonding pad 585 in the second bonding layer 580 may be bonded to the fourth bonding pad 795 in the fourth bonding layer 790 to form a first bonding pad structure.

In example implementations, the third bonding layer 590 of a lower one of the second semiconductor chips 500 included in the second semiconductor chip stack structure may be bonded to the second bonding layer 580 of an upper one of the second semiconductor chips 500 included in the second semiconductor chip stack structure to form a second bonding layer structure, and the third bonding pad 595 in the third bonding layer 590 may be bonded to the second bonding pad 585 in the second bonding layer 580 to form a second bonding pad structure.

The first semiconductor chip 300 may include a second substrate 310 having first and second surfaces 312 and 314 opposite to each other in the vertical direction, and a first insulating interlayer, a second insulating interlayer 330 and a first bonding layer 380 sequentially stacked on the first surface 312 of the second substrate 310 in the vertical direction.

The second substrate 310 may include a semiconductor material, e.g., silicon, germanium, silicon-germanium, or a III-V group compound semiconductor, e.g., GaP, GaAs, GaSb, etc. In example implementations, the second substrate 310 may be a SOI substrate or a GOI substrate.

The second substrate 310, that is, the first semiconductor chip 300 may have a third planar area in the horizontal direction. In example implementations, the third planar area of the second substrate 310 may be equal to the second planar area of the third substrate 510, and may be smaller than the first planar area of the fourth substrate 710. In example implementations, an edge portion of the third semiconductor chip 700 may not overlap the first semiconductor chip 300 in the vertical direction. In an example implementation, a sidewall of the first semiconductor chip 300 may be aligned with the sidewalls of the second semiconductor chips 500 included in the second semiconductor chip stack structure in the vertical direction.

A circuit device, e.g., a volatile memory device such as a DRAM device, an SRAM device, etc., or a non-volatile memory device such as a flash memory device, an EEPROM device, etc., may be disposed on the first surface 312 of the second substrate 310, and thus the first surface 312 facing the second semiconductor chip 500 may be an active surface of the second substrate 310. The circuit device may include circuit patterns, which may be covered by the first insulating interlayer.

The second insulating interlayer 330 may include a first wiring structure 340 therein. The first wiring structure 340 may include, e.g., wirings, vias, contact plugs, etc., and FIG. 1 shows only a single layer for the first wiring structure 340 in order to avoid the complexity of the drawing.

A first bonding pad 385 may be disposed in the first bonding layer 380, and may contact a portion of the first wiring structure 340 to be electrically connected thereto. A plurality of first bonding pads 385 may be spaced apart from each other in the horizontal direction.

In example implementations, the first bonding layer 380 of the first semiconductor chip 300 may be bonded to the third bonding layer 590 of an uppermost one of the second semiconductor chips 500 included in the second semiconductor chip stack structure to form a third bonding layer structure, and the first bonding pad 385 in the first bonding layer 380 may be bonded to the third bonding pad 595 in the third bonding layer 590 to form a third bonding pad structure.

Each of the first, third and fifth insulating interlayers, the second, fourth and sixth insulating interlayers 330, 530 and 730 and the passivation layer 780 may include, e.g., silicon oxide or a low-k dielectric material such as an oxide doped with carbon or fluorine. Each of the wirings, the vias and the contact plugs of the first and second through electrodes 720 and 520, the first conductive pad 785 and the first to third wiring structures 340, 540 and 740 may include a conductive material, e.g., a metal, a metal nitride, a metal silicide, etc.

In example implementations, each of the first to fourth bonding layers 380, 580, 590 and 790 may include, e.g. silicon carbonitride, silicon oxide, or a combination thereof, etc., and each of the first to fourth bonding pads 385, 585, 595 and 795 may include a metal, e.g., copper.

The dummy chip 100 may include a first substrate 110 having first and second surfaces 112 and 114 opposite to each other in the vertical direction.

The first substrate 110 may include a semiconductor material, e.g., silicon, germanium, silicon-germanium, or a III-V group compound semiconductor, e.g., GaP, GaAs, GaSb, etc. In example implementations, the first substrate 110 may be a SOI substrate or a GOI substrate.

The first substrate 110, that is, the dummy chip 100 may have a fourth planar area in the horizontal direction. In example implementations, the fourth planar area may be greater than the first to third planar areas. Thus, an edge portion of the dummy chip 100 may not overlap the first to third semiconductor chips 300, 500 and 700 in the vertical direction.

The first adhesion layer 200 may be interposed between the second surface 314 of the second substrate 310 included in the first semiconductor chip 300 and the first surface 112 of the first substrate 110 included in the dummy chip 100, and thus the first semiconductor chip 300 and the dummy chip 100 may be bonded with each other. The first adhesion layer 200 may include, e.g., non-conductive film (NCF), die attach film (DAF), etc.

The molding member 600 may include, e.g., epoxy molding compound (EMC).

The first conductive connection member 800 may be disposed on a lower surface of the passivation layer 780, and may contact the first conductive pad 785 to be electrically connected thereto. In example implementations, a plurality of first conductive connection members 800 may be spaced apart from each other in the horizontal direction. The first conductive connection member 800 may include a conductive bump or a conductive ball including, e.g., solder.

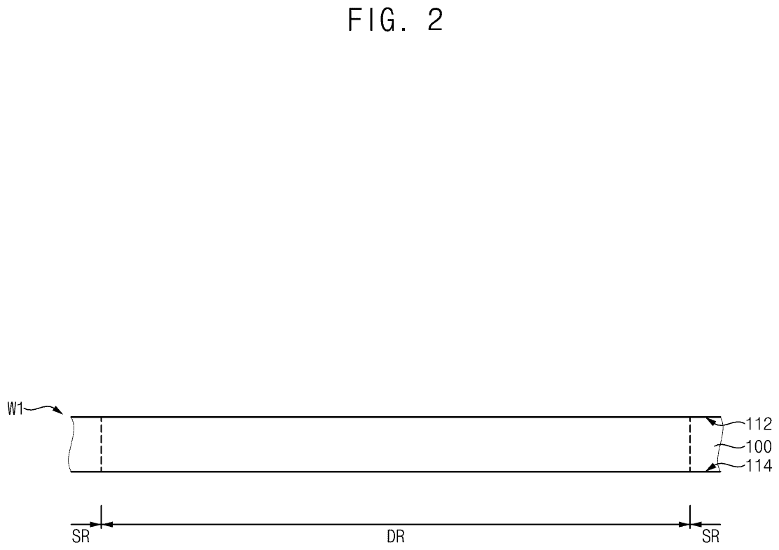

As illustrated below with reference to FIGS. 2 to 11, delamination may not occur at a boundary between the dummy chip 100 and the first semiconductor chip 300 or at a boundary between the second semiconductor chip 500 and the third semiconductor chip 700, and thus the semiconductor package may have enhanced structural stability and enhanced electrical characteristics. Additionally, the dummy chip 100 including a semiconductor material having a CTE greater than that of the molding member 600 may have a relatively large planar area, so that the semiconductor package including the dummy chip 100 may have an enhanced heat emission characteristic.

FIGS. 2 to 11 are cross-sectional views illustrating a method of manufacturing a semiconductor package in accordance with example implementations.

Referring to FIG. 2, a first wafer W1 including a first substrate 110 having first and second surfaces 112 and 114 opposite to each other in the vertical direction may be provided.

The first wafer W1 may include a plurality of die regions DRs and a scribe lane region SR surrounding each of the die regions DRs. The first wafer W1 may be cut along the scribe lane region SR by a sawing process to be singulated into a plurality of dummy chips.

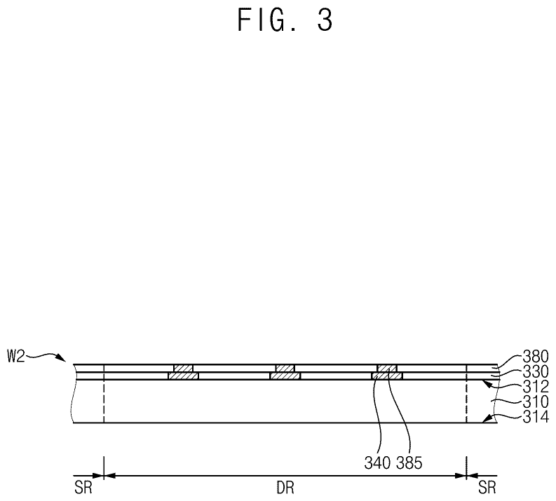

Referring to FIG. 3, a second wafer W2 including a second substrate 310 having first and second surfaces 312 and 314 opposite to each other in the vertical direction may be provided.

The second wafer W2 may include a plurality of die regions DRs and a scribe lane region SR surrounding each of the die regions DRs. The second wafer W2 may be cut along the scribe lane region SR by a sawing process to be singulated into a plurality of first semiconductor chips.

In the die region DR, a circuit device may be formed on the first surface 312 of the second substrate 310. The circuit device may include a logic device. The circuit device may include circuit patterns, and a first insulating interlayer may be formed on the first surface 312 of the second substrate 310 to cover the circuit patterns.

A second insulating interlayer 330 may be formed on the first insulating interlayer, and may include a first wiring structure 340 therein. The first wiring structure 340 may include, e.g., wirings, vias, contact plugs, etc., which are shown as a single layer in FIG. 3.

A first bonding layer 380 including a first bonding pad 385 may be formed on the second insulating interlayer 330 and the first wiring structure 340. In example implementations, a plurality of first bonding pads 385 may be spaced apart from each other in the horizontal direction.

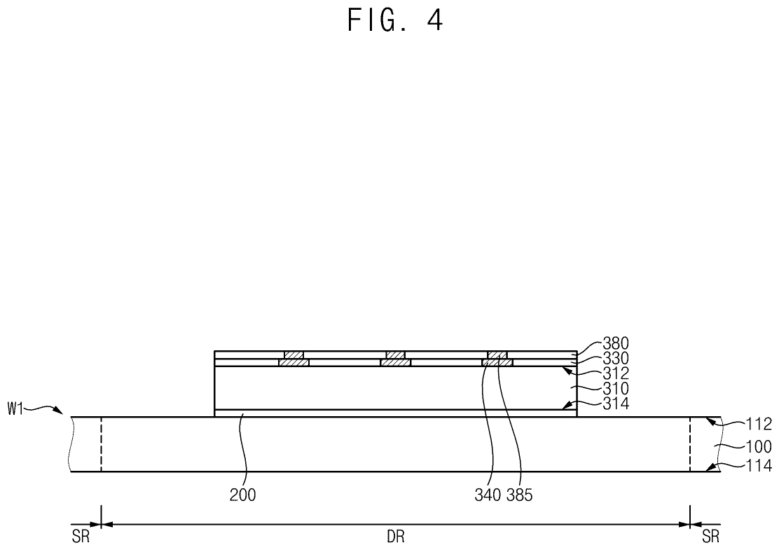

Referring to FIG. 4, a first adhesion layer 200 may be attached to the second surface 314 of the second substrate 310, and the second wafer W2 may be cut along the scribe lane region SR by, e.g., a sawing process to be singulated into a plurality of first semiconductor chips 300.

The first adhesion layer 200 attached to the second surface 314 of each of the first semiconductor chips 300 may be bonded to the first surface 112 of the first substrate 110 included in the first wafer W1. Each of the first semiconductor chips 300 may be mounted onto a corresponding one of the die regions DRs.

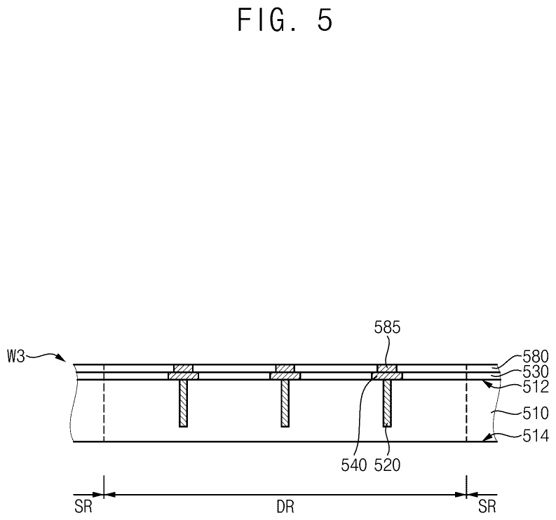

Referring to FIG. 5, a third wafer W3 including a third substrate 510 having first and second surfaces 512 and 514 opposite to each other in the vertical direction may be provided.

The third wafer W3 may include a plurality of die regions DRs and a scribe lane region SR surrounding each of the die regions DRs. The third wafer W3 may be cut along the scribe lane region SR by a sawing process to be singulated into a plurality of second semiconductor chips.

In the die region DR, a circuit device may be formed on the first surface 512 of the third substrate 510. The circuit device may include a memory device. The circuit device may include circuit patterns, and a third insulating interlayer may be formed on the first surface 512 of the third substrate 510 to cover the circuit patterns.

A fourth insulating interlayer 530 may be formed on the third insulating interlayer, and may include a second wiring structure 540 therein. The second wiring structure 540 may include, e.g., wirings, vias, contact plugs, etc., which are shown as a single layer in FIG. 5.

A second through electrode 520 extending in the vertical direction through an upper portion of the third substrate 510, that is, a portion of the third substrate 510 adjacent to the first surface 512 thereof may be formed. In example implementations, a plurality of second through electrodes 520 may be spaced apart from each other in the horizontal direction in each of the die regions DRs of the third wafer W3.

A second bonding layer 580 including a second bonding pad 585 may be formed on the fourth insulating interlayer 530 and the second wiring structure 540. In example implementations, a plurality of second bonding pads 585 may be spaced apart from each other in the horizontal direction. Each of the second bonding pads 585 may contact an upper surface of the second wiring structure 540, and may be electrically connected thereto.

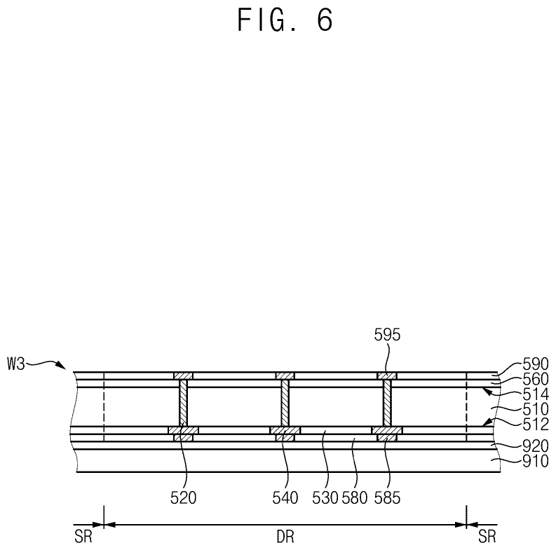

Referring to FIG. 6, a first temporary bonding layer 920 may be attached to a first carrier substrate 910, the first temporary bonding layer 920 may be bonded to an upper surface of the second bonding layer 580 so that the first carrier substrate 910 may be bonded to the third wafer W3, and the first carrier substrate 910 may be flipped.

The first carrier substrate 910 may include, e.g., a non-metallic or metallic plate, a silicon substrate, a glass substrate, etc. The first temporary bonding layer 920 may include a material losing adhesion by irradiation of light, e.g., UV light or heat.

A portion of the third substrate 510 adjacent to the second surface 514 of the third substrate 510 may be removed by, e.g., a grinding process to expose an upper portion of the second through electrode structure 520, a first protective layer structure may be formed on the second surface 514 of the third substrate 510 to cover the second through electrode 520, and a planarization process may be performed on the first protective layer structure until an upper surface of the second through electrode 520 is exposed to form a second protective pattern structure 560.

A third bonding layer 590 including a second bonding pad 595 may be formed on the second protective pattern structure 560 and the second through electrode 520. In example implementations, a plurality of third bonding pads 595 may be spaced apart from each other in the horizontal direction. Each of the third bonding pads 595 may contact an upper surface of the second through electrode 520, and may be electrically connected thereto.

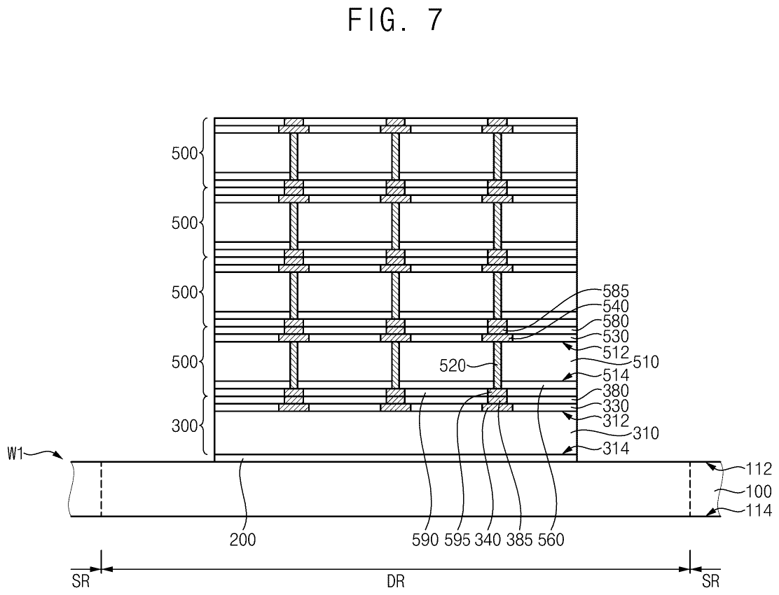

Referring to FIG. 7, the third wafer W3 may be cut along the scribe lane region SR by, e.g., a sawing process to be singulated into a plurality of second semiconductor chips 500, and each of the second semiconductor chips 500 and the first semiconductor chip 300 may be bonded with each other by a hybrid copper bonding (HCB) process, and the first temperature bonding layer 920 and the first carrier substrate 910 may be separated from each of the second semiconductor chips 500.

In example implementations, the third bonding layer 590 on the second semiconductor chip 500 and the first bonding layer 380 on the first semiconductor chip 300 may contact each other so that the first and second semiconductor chips 300 and 500 may be bonded with each other, and the third bonding pad 595 in the third bonding layer 590 and the first bonding pad 385 in the first bonding layer 380 may contact each other.

A plurality of second semiconductor chips 500 may be further bonded to the second semiconductor chip 500 bonded to the first semiconductor chip 300 by an HCB process, and the second semiconductor chips 500 sequentially stacked on the first semiconductor chip 300 may collectively form a second semiconductor chip stack structure. The second bonding layer 580 of a lower one of the second semiconductor chips 500 and the third bonding layer 590 of an upper one of the second semiconductor chips 500 may be bonded with each other, and the second bonding pad 585 in the second bonding layer 580 and the third bonding pad 595 in the third bonding layer 590 may contact each other.

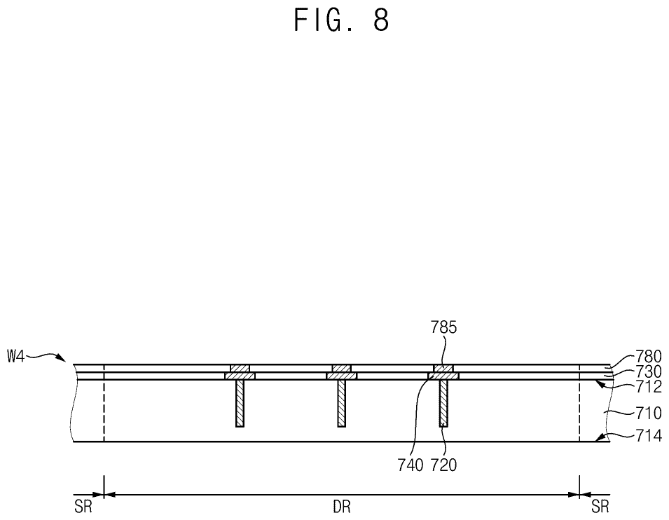

Referring to FIG. 8, a fourth wafer W4 including a fourth substrate 710 having first and second surfaces 712 and 714 opposite to each other in the vertical direction may be provided.

The fourth wafer W4 may include a plurality of die regions DRs and a scribe lane region SR surrounding each of the die regions DRs. The fourth wafer W4 may be cut along the scribe lane region SR by a sawing process to be singulated into a plurality of third semiconductor chips.

In the die region DR, a circuit device may be formed on the first surface 712 of the fourth substrate 710. The circuit device may include a logic device. The circuit device may include circuit patterns, and a fifth insulating interlayer may be formed on the first surface 712 of the fourth substrate 710 to cover the circuit patterns.

A sixth insulating interlayer 730 may be formed on the fifth insulating interlayer, and may include a third wiring structure 740 therein. The third wiring structure 740 may include, e.g., wirings, vias, contact plugs, etc., which are shown as a single layer in FIG. 8.

A passivation layer 780 including a first conductive pad 785 may be formed on the sixth insulating interlayer 730. In example implementations, a plurality of first conductive pads 785 may be spaced apart from each other in the horizontal direction. Each of the first conductive pads 785 may contact an upper surface of a portion of the third wiring structure 740, and may be electrically connected thereto.

A first through electrode 720 extending in the vertical direction through an upper portion of the fourth substrate 710, that is, a portion of the fourth substrate 710 adjacent to the first surface 712 thereof may be formed. In example implementations, a plurality of first through electrodes 720 may be spaced apart from each other in the horizontal direction in each of the die regions DRs of the fourth wafer W4.

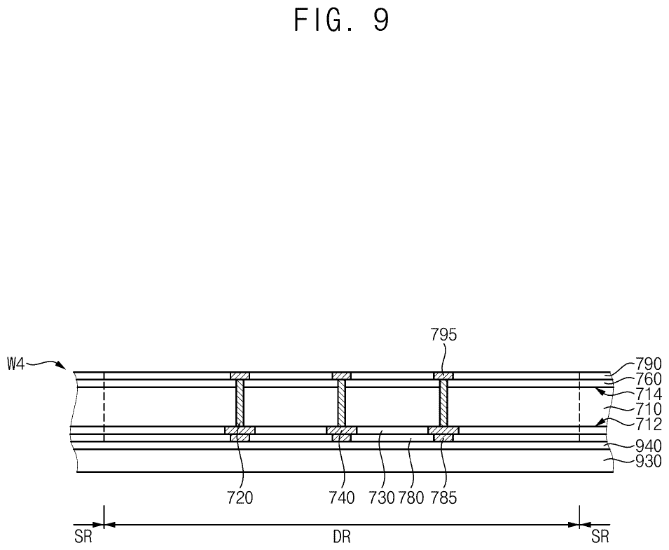

Referring to FIG. 9, a second temporary bonding layer 940 may be attached to a second carrier substrate 930, the second temporary bonding layer 940 may be bonded to an upper surface of the passivation layer 780 so that the second carrier substrate 930 may be bonded to the fourth wafer W4, and the second carrier substrate 930 may be flipped.

The second carrier substrate 930 may include, e.g., a non-metallic or metallic plate, a silicon substrate, a glass substrate, etc. The second temporary bonding layer 940 may include a material losing adhesion by irradiation of light, e.g., UV light or heat.

A portion of the fourth substrate 710 adjacent to the second surface 714 of the fourth substrate 710 may be removed by, e.g., a grinding process to expose an upper portion of the first through electrode structure 720, a second protective layer structure may be formed on the second surface 714 of the fourth substrate 710 to cover the first through electrode 720, and a planarization process may be performed on the second protective layer structure until an upper surface of the first through electrode 720 is exposed to form a first protective pattern structure 760.

A fourth bonding layer 790 including a fourth bonding pad 795 may be formed on the first protective pattern structure 760 and the first through electrode 720. In example implementations, a plurality of fourth bonding pads 795 may be spaced apart from each other in the horizontal direction. Each of the fourth bonding pads 795 may contact an upper surface of the first through electrode 720, and may be electrically connected thereto.

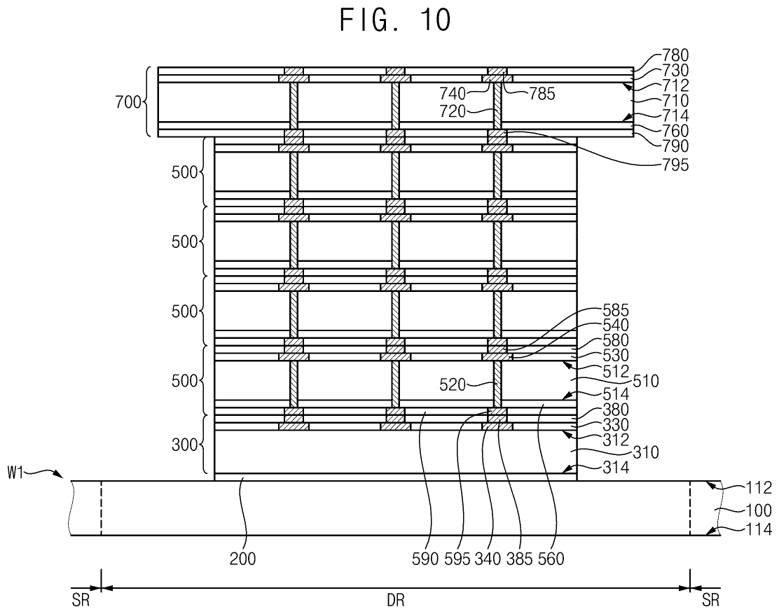

Referring to FIG. 10, the fourth wafer W4 may be cut along the scribe lane region SR by, e.g., a sawing process to be singulated into a plurality of third semiconductor chips 700, and each of the third semiconductor chips 700 and an uppermost one of the second semiconductor chips 500 included in the second semiconductor chip stack structure may be bonded with each other by an HCB process, and the second temperature bonding layer 940 and the second carrier substrate 930 may be separated from each of the third semiconductor chips 700.

In example implementations, the fourth bonding layer 790 on the third semiconductor chip 700 and the second bonding layer 580 on the second semiconductor chip 500 may contact each other so that the second and third semiconductor chips 500 and 700 may be bonded with each other, and the fourth bonding pad 795 in the fourth bonding layer 790 and the second bonding pad 585 in the second bonding layer 580 may contact each other.

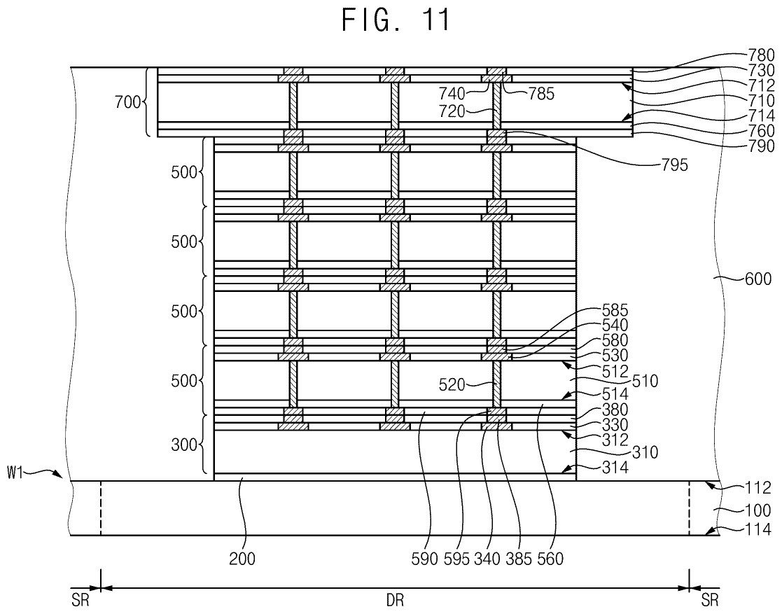

Referring to FIG. 11, a molding member 600 may be formed on the first wafer W1 to cover sidewalls of the first bonding layer 200, the first semiconductor chip 300, the second semiconductor chip stack structure and the third semiconductor chip 700.

Referring to FIG. 1, the first wafer W1 may be cut along the scribe lane region SR by, e.g., a sawing process to be singulated into a plurality of dummy chips 100, and the molding member 600 on the first wafer W1 may also be cut to cover the sidewalls of the first bonding layer 200, the first semiconductor chip 300, the second semiconductor chip stack structure and the third semiconductor chip 700 on each of the dummy chips 100.

A first conductive connection member 800 may be formed on a lower surface of the passivation layer 780 to complete the manufacturing of the semiconductor package.

As illustrated above, the first to third semiconductor chips 300, 500 and 700 may be stacked on the first wafer W1, which may be singulated into the dummy chips 100.

Generally, a ratio of non-defective third semiconductor chips 700 among all of the third semiconductor chips 700 produced from the fourth wafer W4 including logic devices is lower than a ratio of non-defective first semiconductor chips 300 or non-defective second semiconductor chips 500 among all of the first semiconductor chips 300 or among all of the second semiconductor chips 500 produced from the second wafer W4 including memory devices. Further, the ratio of the non-defective third semiconductor chips 700 among all of the third semiconductor chips 700 produced from the fourth wafer W4 including the logic devices is much lower than a ratio of non-defective dummy chips 100 among all of the dummy chips 100 produced from the first wafer W1.

If the first and second semiconductor chips 300 and 500 are stacked on the fourth wafer W4, the first and second semiconductor chips 300 and 500 may also be stacked on a defective one of the third semiconductor chips 700. Thus, after the fourth wafer W4 is singulated into a plurality of third semiconductor chips 700, all of the defective one of the third semiconductor chips 700 and the first and second semiconductor chips 300 and 500 stacked thereon may be lost.

However, in example implementations, the first to third semiconductor chips 300, 500 and 700 may be stacked on the first wafer W1 having a very high ratio of non-defective dummy chip 100 to manufacture the semiconductor package, so that cost associated with the defective dummy chip 100 may be reduced.

During the manufacturing of the semiconductor package, a warpage direction of the fourth wafer W4 including logic devices may be opposite to a warpage direction of the first and second semiconductor chips 300 and 500 including memory devices. Thus, delamination may occur at a boundary between the first and second semiconductor chips 300 and 500, particularly, at edge portions of the first and second semiconductor chips 300 and 500.

However, in example implementations, a warpage direction of the first wafer W1, which may be singulated into the dummy chips 100, may be flat, and thus may not be opposite to the warpage direction of the first and second semiconductor chips 300 and 500. Accordingly, delamination may not occur at the boundary between the first and second semiconductor chips 300 and 500 during the manufacturing of the semiconductor package.

Additionally, instead of being bonded to the first and second semiconductor chips 300 and 500 in its wafer state, the fourth wafer W4 including the logic devices may be bonded to the second semiconductor chip 500 in the form of the third semiconductor chip 700. Thus, delamination caused by different warpage directions of the first to third semiconductor chips 300, 500 and 700 may be reduced.

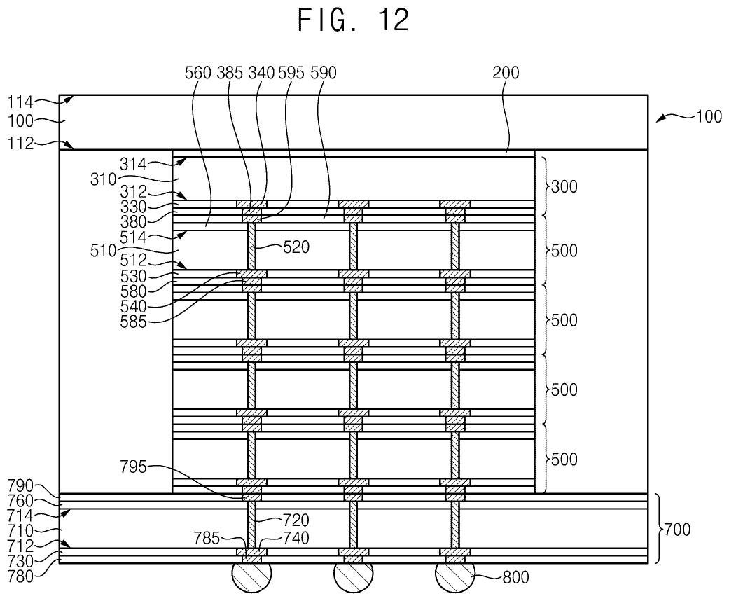

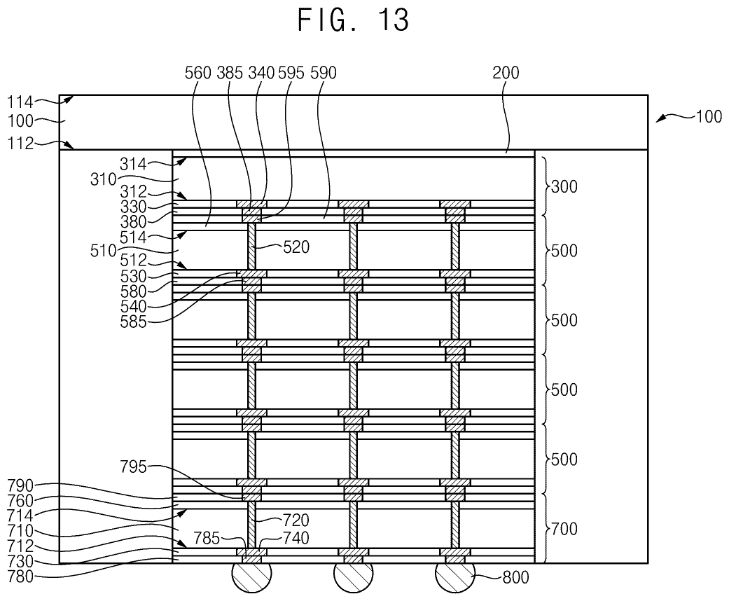

FIGS. 12 and 13 are cross-sectional views illustrating semiconductor packages in accordance with example implementations. These semiconductor packages may be substantially the same as or similar to that of FIG. 1, except for the size of the third semiconductor chip 700, and thus repeated explanations are omitted herein.

Referring to FIG. 12, the first planar area of the third semiconductor chip 700 may be substantially the same as the fourth planar area of the dummy chip 100.

Thus, the molding member 600 may be disposed between the third semiconductor chip 700 and the dummy chip 100, and may not cover the sidewall of the third semiconductor chip 700.

Referring to FIG. 13, the first planar area of the third semiconductor chip 700 may be substantially the same as the second and third planar areas of the first and second semiconductor chips 300 and 500.

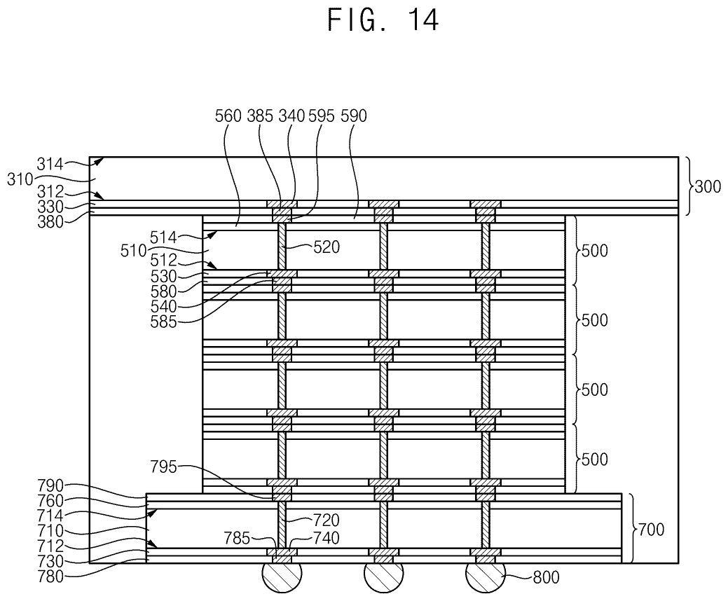

FIG. 14 is a cross-sectional view illustrating a semiconductor package in accordance with example implementations. This semiconductor package may be substantially the same as or similar to that of FIG. 1, except for not including the dummy chip 100 and the size of the first semiconductor chip 300, and thus repeated explanations are omitted herein.

Referring to FIG. 14, the third planar area of the first semiconductor chip 300 may be greater than the first planar area of the third semiconductor chip 700.

Thus, the edge portion of the first semiconductor chip 300 may not overlap the second and third semiconductor chips 500 and 700 in the vertical direction.

The semiconductor package may not include the dummy chip 100.

The semiconductor package may be manufactured by stacking the second and third semiconductor chips 500 and 700 on the second wafer W2, which may be singulated into the first semiconductor chips 300. The ratio of the non-defective first semiconductor chips 300 among all of the first semiconductor chips 300 produced from the second wafer W2 including the memory devices is greater than the ratio of non-defective third semiconductor chips 700 among all of the third semiconductor chips 700 produced from the fourth wafer W4 including the logic devices, and thus the cost associated with the defective first semiconductor chips 300 may be reduced.

Additionally, the second wafer W2 may include the memory device, which is the same as the second semiconductor chips 500, and thus, during the manufacturing of the semiconductor package, delamination due to the different warpage directions may be prevented.

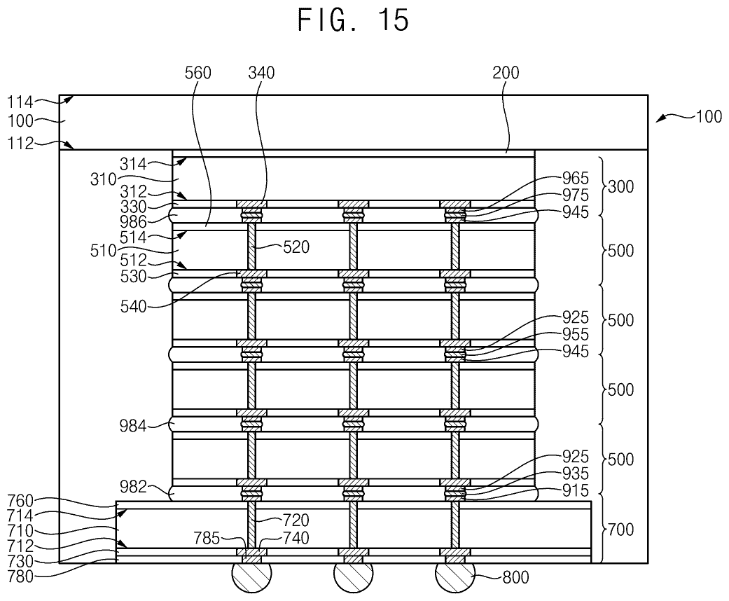

FIG. 15 is a cross-sectional view illustrating a semiconductor package in accordance with example implementations. This semiconductor package may be substantially the same as or similar to that of FIG. 1, except that the first to third semiconductor chips 300, 500 and 700 are bonded with each other not by an HCB process but by a thermal compression bonding (TCB) process, and thus repeated explanations are omitted herein.

Referring to FIG. 15, the semiconductor package may not include the first to third bonding layer structures and the first to third bonding pad structures, but may include second to fifth conductive pads 915, 925, 945 and 965 and second to fourth conductive connection members 935, 955 and 975.

The second conductive pad 915 may be disposed on an upper surface of the first protective pattern structure 760 of the third semiconductor chip 700, and may contact an upper surface of the first through electrode 720. The third conductive pad 925 may be disposed on a lower surface of the fourth insulating interlayer 530 of the second semiconductor chip 500, and may contact a portion of the second wiring structure 540. The fourth conductive pad 945 may be disposed on an upper surface of the second protective pattern structure 560 of the second semiconductor chip 500, and may contact an upper surface of the second through electrode 520. The fifth conductive pad 965 may be disposed on a lower surface of the second insulating interlayer 330 of the first semiconductor chip 300, and may contact a portion of the first wiring structure 340.

Each of the second to fifth conductive pads 915, 925, 945 and 965 may include, e.g., a metal, a metal nitride, a metal silicide, etc.

The second conductive connection member 935 may be interposed between the second and third conductive pads 915 and 925, and may bond the second and third conductive pads 915 and 925 to each other. The third conductive connection member 955 may be interposed between the third and fourth conductive pads 925 and 945, and may bond the third and fourth conductive pads 925 and 945 to each other. The fourth conductive connection member 975 may be interposed between the fourth and fifth conductive pads 945 and 965, and may bond the fourth and fifth conductive pads 945 and 965 to each other.

In example implementations, each of the second to fourth conductive connection members 935, 955 and 975 may include a conductive bump or a conductive ball including, e.g., solder.

The semiconductor package may further include second to fourth adhesion layers 982, 984 and 986.

The second adhesion layer 982 may be interposed between the third semiconductor chip 700 and a lowermost one of the second semiconductor chips 500 included in the second semiconductor chip stack structure, and may cover sidewalls of the second and third conductive pads 915 and 925 and the second conductive connection member 935. The third adhesion layer 984 may be interposed between the second chips 500 included in the second semiconductor chip stack structure, and may cover sidewalls of the third and fourth conductive pads 925 and 945 and the third conductive connection member 955. The fourth adhesion layer 986 may be interposed between an uppermost one of the second semiconductor chips 500 included in the second semiconductor chip stack structure and the first semiconductor chip 300, and may cover sidewalls of the fourth and fifth conductive pads 945 and 965 and the fourth conductive connection member 975.

Each of the second to fourth adhesion layers 982, 984 and 986 may include, e.g., NCF, DAF, etc.

FIG. 15 shows that all of the first to third semiconductor chips 300, 500 and 700 are bonded with each other by a TCB process, however, the implementations of present disclosure is not necessarily limited thereto, and for example, some ones of the first to third semiconductor chips 300, 500 and 700 may be bonded with each other by a TCB process and other ones of the first to third semiconductor chips 300, 500 and 700 may be bonded with each other by an HCB process.

FIG. 15 shows that the semiconductor chips in the semiconductor package of FIG. 1 are bonded with each other by a TCB process, however, the present disclosure is not necessarily limited thereto, and for example, the semiconductor chips in any one of the semiconductor packages of FIGS. 12 to 14 may be bonded with each other by a TCB process.

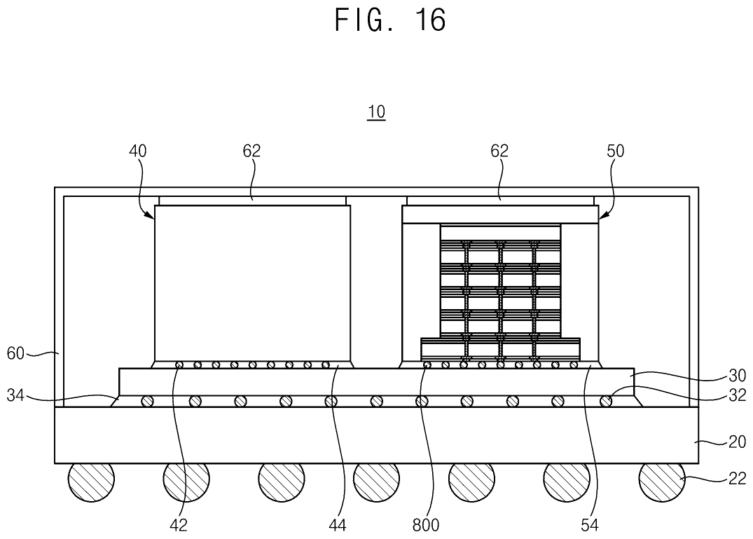

FIG. 16 is a cross-sectional view illustrating an electronic device in accordance with example implementations.

This electronic device may include the semiconductor package shown in FIG. 1 as a second semiconductor device 50, however, the present disclosure may not be limited thereto, and for example, the electronic device may include one of the semiconductor packages shown in FIGS. 12 to 15 as the second semiconductor device 50.

Referring to FIG. 16, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example implementations, the electronic device 10 may be a memory module having a 2.5D package structure, and thus may include the interposer 30 for electrically connecting the first and second semiconductor devices 40 and 50 to each other.

In example implementations, the first semiconductor device 40 may include a logic device, and the second semiconductor device 50 may include the semiconductor package of FIG. 1. The logic device may be an application-specific integrated circuit (ASIC) chip including, e.g., a central processing unit (CPU), a graphics processing unit (GPU), a micro-processor, a micro-controller, an application processor (AP), a digital signal processing core, etc.

In example implementations, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a seventh conductive connection member 32. In example implementations, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the sixth conductive connection member 32. The sixth conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a TCB process. The first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a seventh conductive connection member 42. For example, the seventh conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by a TCB process. Conductive pads of the second semiconductor device 50 may be electrically connected to conductive pads of the interposer 30 by the first conductive connection member 800.

Although a single first semiconductor device 40 and a single second semiconductor device 50 are disposed on the interposer 30, however, the present disclosure may not be limited thereto, and a plurality of first semiconductor devices 40 and/or a plurality of second conductive devices 50 may be disposed on the interposer 30.

In example implementations, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members34, 44 and 54 may include an adhesive containing an epoxy material.

In example implementations, the heat slug 60 may be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a fifth conductive connection member 22 may be disposed beneath the conductive pad. In example implementations, a plurality of fifth conductive connection members 22 may be spaced apart from each other in the horizontal direction. The fifth conductive connection member 22 may be, e.g., a solder ball. The electronic device 10 may be mounted on a module board via the sixth conductive connection members 22 to form a memory module.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a buffer die having a first planar area;
a memory die stack structure including middle core dies and a top core die that are stacked on the buffer die in a vertical direction, the memory die stack structure having a second planar area smaller than the first planar area;
an adhesion layer contacting an upper surface of the memory die stack structure;
a dummy die contacting the adhesion layer, the dummy die having a third planar area greater than the first planar area; and
a molding structure under the dummy die, the molding structure covering sidewalls of the buffer die, the memory die stack structure, and the adhesion layer.

2. The semiconductor package of claim 1, wherein the middle core dies are bonded with each other through a respective bonding layer structure, the respective bonding layer structure including a respective bonding pad structure.

3. The semiconductor package of claim 2, wherein the respective bonding layer structure includes silicon carbonitride and/or silicon oxide, and
wherein the respective bonding pad structure includes copper.

4. The semiconductor package of claim 1, wherein a lowermost middle core die of the middle core dies and the buffer die are bonded with each other through a bonding layer structure, the bonding layer structure including a bonding pad structure.

5. The semiconductor package of claim 4, wherein the bonding layer structure includes silicon carbonitride and/or silicon oxide, and
wherein the bonding pad structure includes copper.

6. The semiconductor package of claim 1, wherein an uppermost middle core die of the middle core dies and the top core die are bonded with each other through a bonding layer structure including a bonding pad structure.

7. The semiconductor package of claim 6, wherein the bonding layer structure includes silicon carbonitride and/or silicon oxide, and
wherein the bonding pad structure includes copper.

8. The semiconductor package of claim 1, wherein the adhesion layer includes a non-conductive film (NCF) and/or a die attach film (DAF).

9. The semiconductor package of claim 1, wherein each of the middle core dies includes:
a substrate having a first surface and a second surface opposite to each other in the vertical direction;
a through electrode extending through the substrate, the through electrode including a protrusion portion that protrudes over the second surface of the substrate;
a protective pattern structure on the second surface of the substrate, the protective pattern structure covering a sidewall of the protrusion portion of the through electrode; and
a wiring structure on the first surface of the substrate, the wiring structure being electrically connected to the through electrode.

10. The semiconductor package of claim 1, wherein the buffer die includes:
a substrate having a first surface and a second surface opposite to each other in the vertical direction;
a through electrode extending through the substrate, the through electrode including a protrusion portion that protrudes over the second surface of the substrate;
a protective pattern structure on the second surface of the substrate and covering a sidewall of the protrusion portion of the through electrode;
a wiring structure on the first surface of the substrate, the wiring structure being electrically connected to the through electrode; and
a conductive pad contacting a portion of the wiring structure.

11. The semiconductor package of claim 10, further comprising a conductive bump contacting a lower surface of the conductive pad.

12. The semiconductor package of claim 1, wherein the top core die includes a substrate having a first surface and a second surface opposite to each other in the vertical direction, and
wherein the substrate is free of a through electrode extending through the substrate.

13. The semiconductor package of claim 1, wherein the dummy die includes a semiconductor material.

14. A semiconductor package comprising:
a logic chip having a first planar area;
a memory chip stack structure including first memory chips stacked on the logic chip in a vertical direction, the memory chip stack structure being bonded with the logic chip through a first bonding layer structure, the first bonding layer structure including a first bonding pad structure;
a second memory chip on the memory chip stack structure, the second memory chip being bonded with the memory chip stack structure through a second bonding layer structure, the second bonding layer structure including a second bonding pad structure;
a dummy chip on the second memory chip, the dummy chip being bonded with the second memory chip through an adhesion layer, and the dummy chip having a second planar area greater than the first planar area; and
a molding structure under the dummy chip, the molding structure covering sidewalls of the logic chip, the memory chip stack structure, the second memory chip, the first and second bonding layer structures, and the adhesion layer.

15. The semiconductor package of claim 14, wherein each of the first and second bonding layer structures includes silicon carbonitride and/or silicon oxide, and
wherein each of the first and second bonding pad structures includes copper.

16. The semiconductor package of claim 14, wherein the first memory chips are bonded with each other through a respective third bonding layer structure, the respective third bonding layer structure including a respective third bonding pad structure.

17. The semiconductor package of claim 14, wherein the adhesion layer includes non-conductive film (NCF) and/or die attach film (DAF).

18. A semiconductor package comprising:
a logic chip having a first planar area;
a memory chip stack structure including first memory chips that are stacked on the logic chip in a vertical direction, the first memory chips being bonded with each other through a respective first bonding layer structure that includes a respective first bonding pad structure, the memory chip stack structure being bonded with the logic chip through a second bonding layer structure that includes a second bonding pad structure, and the memory chip stack structure having a second planar area smaller than the first planar area;
a second memory chip on the memory chip stack structure, the second memory chip being bonded with the memory chip stack structure through a third bonding layer structure that includes a second bonding pad structure, and the second memory chip having the second planar area;
a dummy chip on the second memory chip, the dummy chip being bonded with the second memory chip through an adhesion layer, and the dummy chip having a third planar area greater than the first planar area;
a molding structure under the dummy chip, the molding structure covering sidewalls of the logic chip, the memory chip stack structure, the second memory chip, the first to third bonding layer structures, and the adhesion layer; and
a conductive bump contacting a lower surface of the logic chip.

19. The semiconductor package of claim 18, wherein each of the first to third bonding layer structures includes silicon carbonitride and/or silicon oxide, and
wherein each of the first to third bonding pad structures includes copper.

20. The semiconductor package of claim 18, wherein the adhesion layer includes non-conductive film (NCF) and/or die attach film (DAF).
